(19) United States
(12) Patent Application Publication
(10) Pub. No.: US 2023/0178421 A1
(43) Pub. Date: Jun. 8, 2023

(54) SUBTRACTIVE LINE WITH DAMASCENE TOP VIA

(71) Applicant: International Business Machines Corporation, Armonk, NY (US)

(72) Inventors: Chanro Park, Clifton Park, NY (US); Koichi Motoyama, Clifton Park, NY (US); Hsueh-Chung Chen, Cohoes, NY (US); Chih-Chao Yang, Glenmont, NY (US)

(21) Appl. No.: 17/544,136

(22) Filed: Dec. 7, 2021

(51) Int. Cl. H01L 21/768; H01L 23/522

(52) U.S. Cl. CPC H01L 21/76807; H01L 21/76885; H01L 21/7688; H01L 23/5226

(57) ABSTRACT

Embodiments disclosed herein describe semiconductor devices that include semiconductor structures and methods of forming the semiconductor structures. The methods may include forming a subtractive line from a bottom metal layer and a sacrificial hard mask above the bottom metal layer, depositing a scaffolding material around the subtractive line, forming a via mask over a via portion of the sacrificial hard mask and the scaffolding material, etching the sacrificial hard mask that is not covered by the via mask, to form a sacrificial via, removing the via mask and the scaffolding material, depositing a low-κ layer around the subtractive line and the sacrificial via, removing the sacrificial via to form a via hole within the low-κ layer, and forming a top via by metallizing the via hole.

### BACKGROUND

The present invention relates generally to the field of fabrication methods and resulting structures for semiconductor devices, and more particularly to forming a top via in a metal interconnect layer.

In fabricating semiconductor devices, millions of devices can be located together on a single substrate. Useful control of these millions of devices relies on the application of electrical signals to specific devices while insulting the electrical signals from shorting to anything else (e.g., other devices). The electrical signals propagate from the substrate and the package contacts to the devices through metallized layers, which can act as wiring (e.g., channels). Typical integrated circuit packages may include seven or more metallized layers (i.e., M1 to M7). Each metallized layer is insulated from the layer below except for specific connections called vias. Vias are typically formed as openings between layers that are filled with a conductive material during fabrication. Smaller pitch of devices and of vias (i.e., smaller distance between common features of a device or a via) can lead to increases in speed and efficiency of semiconductor devices. The overlay and critical dimension tolerance between line and via of small-pitch devices, however, drives the use of self-aligned features and processes.

### SUMMARY

According to one embodiment of the present invention, a method of forming a semiconductor structure is described. The method may include forming a subtractive line from a bottom metal layer and a sacrificial hard mask above the bottom metal layer, depositing a scaffolding material around the subtractive line, forming a via mask over a via portion of the sacrificial hard mask and the scaffolding material, etching the sacrificial hard mask that is not covered by the via mask, to form a sacrificial via, removing the via mask and the scaffolding material, depositing a low-κ layer around the subtractive line and the sacrificial via, removing the sacrificial via to form a via hole within the low-κ layer, and forming a top via by metallizing the via hole.

According to one embodiment of the present invention, a semiconductor structure, includes a bottom metal layer wire comprising a wire width, a top via above the metal layer wire, wherein the top via comprises a via width that is equal to the wire width, and a low-κ layer surrounding the metal layer wire and the top via.

According to one embodiment of the present invention, a method includes forming a subtractive line comprising a bottom metal layer wire, forming a sacrificial top via above the bottom metal layer wire, depositing a low-κ layer around the bottom metal layer wire and the sacrificial top via, removing the sacrificial top via to form a via hole within the low-κ layer, and forming a top via by metallizing the via hole.

### BRIEF DESCRIPTION OF THE DRAWINGS

FIG. 1A and 1B are a schematic cross-sectional side view and a top view depicting a semiconductor structure at a fabrication stage, in accordance with one embodiment of the present invention;

FIG. 2A and 2B are a schematic cross-sectional side view and a top view depicting the semiconductor structure of FIG. 1 at a subsequent fabrication stage, in accordance with one embodiment of the present invention;

FIG. 3A and 3B are a schematic cross-sectional side view and a top view depicting the semiconductor structure of FIG. 1 at a subsequent fabrication stage, in accordance with one embodiment of the present invention;

FIG. 4A, 4B, and 4C are schematic cross-sectional side views and a top view depicting the semiconductor structure of FIG. 1 at a subsequent fabrication stage, in accordance with one embodiment of the present invention;

FIG. 5A, 5B, and 5C are schematic cross-sectional side views and a top view depicting the semiconductor structure of FIG. 1 at a subsequent fabrication stage, in accordance with one embodiment of the present invention;

FIG. 6A, 6B, and 6C are schematic cross-sectional side views and a top view depicting the semiconductor structure of FIG. 1 at a subsequent fabrication stage, in accordance with one embodiment of the present invention;

FIG. 7A, 7B, and 7C are schematic cross-sectional side views and a top view depicting the semiconductor structure of FIG. 1 at a subsequent fabrication stage, in accordance with one embodiment of the present invention;

FIG. 8A, 8B, and 8C are schematic cross-sectional side views and a top view depicting the semiconductor structure of FIG. 1 at a subsequent fabrication stage, in accordance with one embodiment of the present invention;

FIG. 9A, 9B, and 9C are schematic cross-sectional side views and a top view depicting the semiconductor structure of FIG. 1 at a subsequent fabrication stage, in accordance with one embodiment of the present invention; and

FIG. 10A, 10B, and 10C are schematic cross-sectional side views and a top view depicting the semiconductor structure of FIG. 1 at a subsequent fabrication stage, in accordance with one embodiment of the present invention.

### DETAILED DESCRIPTION

In the following detailed description, reference is made to the accompanying drawings, which show specific examples of embodiments of the invention. These embodiments are described in sufficient detail to enable those skilled in the art to practice them, and it is to be understood that other embodiments may be utilized and that structural, logical and electrical changes may be made without departing from the described embodiments. The following detailed description is, therefore, not to be taken in a limiting sense, and the included embodiments are defined by the appended claims.

Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

References in the specification to “one embodiment,” “an embodiment,” “an example embodiment,” etc., indicate that the embodiment described may include a particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “right,” “left,” “vertical,” “horizontal,” “top,” “bottom,” and derivatives thereof shall relate to the disclosed structures and methods, as oriented in the drawing Figures. The terms “overlaying,” “atop,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

With regard to the fabrication of transistors and integrated circuits, major surface refers to that surface of the semiconductor layer in and about which a plurality of transistors are fabricated, e.g., in a planar process. As used herein, the term “vertical” means substantially orthogonal with respect to the major surface. Typically, the major surface is along a plane of a monocrystalline silicon layer on which transistor devices are fabricated.

For integrated circuits, the formation of more vias in a smaller area can increase the speed and efficiency of the device overall. Circuits with smaller pitch, however, can suffer additional risk of shorting and electrical failure from misalignment during via formation. Specifically, shorting and electrical failure can be exasperated by vias that are broader than the underlying wires, which can happen due to gouging of scaffolding material during damascene via formation. Embodiments disclosed herein therefore provide a subtractive wire formation with a damascene via process that enables a cleaner via formation. Separate processes for wire formation and via formation enable the heights of the via and the wire to be controlled independently.

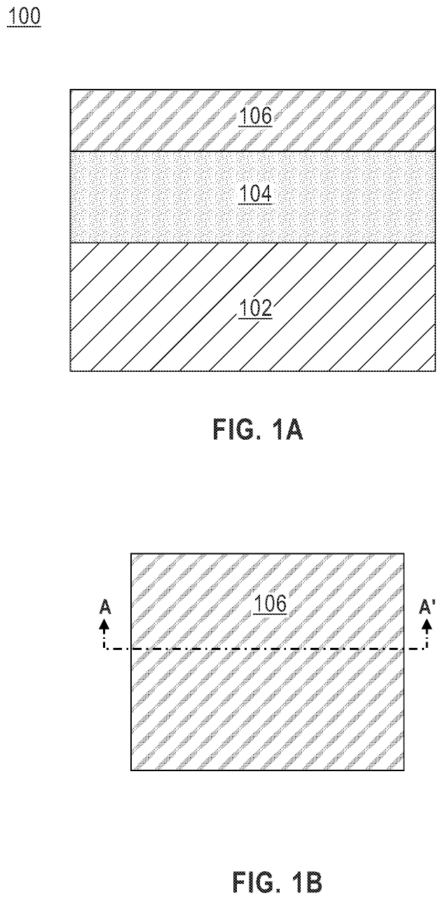

Referring now to the figures, FIG. 1A is a schematic cross-sectional side view depicting a semiconductor structure 100 (e.g., middle of line (MOL) or back end of line (BEOL) wiring structure) at a fabrication stage of the processing method, in accordance with one embodiment of the present invention. FIG. 1 shows blanket layers that include a substrate 102. Above the substrate 102, the semiconductor structure 100 includes a bottom metal layer 104. And above the bottom metal layer 104, the semiconductor structure 100 includes a sacrificial hard mask 106. The bottom metal layer 104 may be the first (i.e., M1) metal layer such that the substrate 102 is a device layer that has transistor devices incorporated therein. The substrate 102 may also be a lower metal layer, such that the bottom metal layer 104 is a subsequent metal layer (i.e., M2, M3, M4) with the device layer being below the substrate 102.

The blanket layers of the bottom metal layer 104 and the sacrificial hard mask 106 may be deposited using known processes such as selective deposition, atomic-layer deposition (ALD), chemical vapor deposition (CVD) and physical vapor deposition (PVD). The bottom metal layer 104 may include conductive materials such as copper, aluminum, tungsten, cobalt, ruthenium, molybdenum, or other metals. The sacrificial hard mask 106 may include any suitable dielectric such as, but not limited to: silicon nitride (SiN), silicon carbide (SiC), silicon oxynitride (SiON), carbon-doped silicon oxide (SiOC), silicon-carbon-nitride (SiCN), boron nitride (BN), silicon boron nitride (SiBN), silicoboron carbonitride (SiBCN), silicon oxycarbonitride (SiOCN), silicon oxide, and combinations thereof. FIG. 1B is a top view of the semiconductor structure 100, showing the cross-sectional view location A-A′ along which FIG. 1A is illustrated. The top view shows only the sacrificial hard mask 106, since the blanket layers (i.e., substrate 102, bottom metal layer 104) are underneath the sacrificial hard mask 106 and hidden from view.

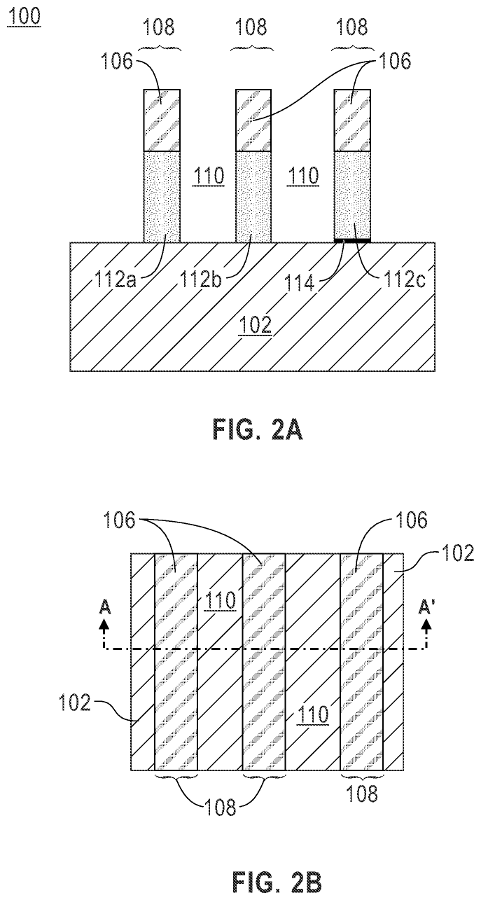

FIG. 2A and 2B are a schematic cross-sectional side view and a top view depicting the semiconductor structure of FIG. 1 at a subsequent fabrication stage, in accordance with one embodiment of the present invention. FIG. 2A shows the sacrificial hard mask 106 and the bottom metal layer 104 etched to form subtractive lines 108. The subtractive lines 108 may be formed by etching the sacrificial hard mask 106 in accordance with a pattern (e.g., lithography mask applied to photoresist), and then etching the bottom metal layer 104 to form spaces 110 between the subtractive line 108. The bottom metal layer 104 at the stage illustrated in FIGS. 2A and 2B forms bottom metal layer wires 112a, b, c that control the signal and/or power delivery to the substrate 102. Many additional bottom metal layer wires and spaces 110 may be formed from the bottom metal layer 104. Some of the bottom metal layer wires 112a, b, c may be formed with a substrate liner 114 between the substrate 102 and the bottom metal layer wire. In embodiments with a substrate liner 114, typically all bottom metal layer wires 112a, b, c would have the substrate liner 114 below, but for illustrative purposes the semiconductor structure 100 only includes the substrate liner 114 under the third bottom metal layer wire 112c. FIG. 2B shows a top view of the semiconductor structure 100, with the substrate 102 visible in the spaces 110 between the subtractive lines 108.

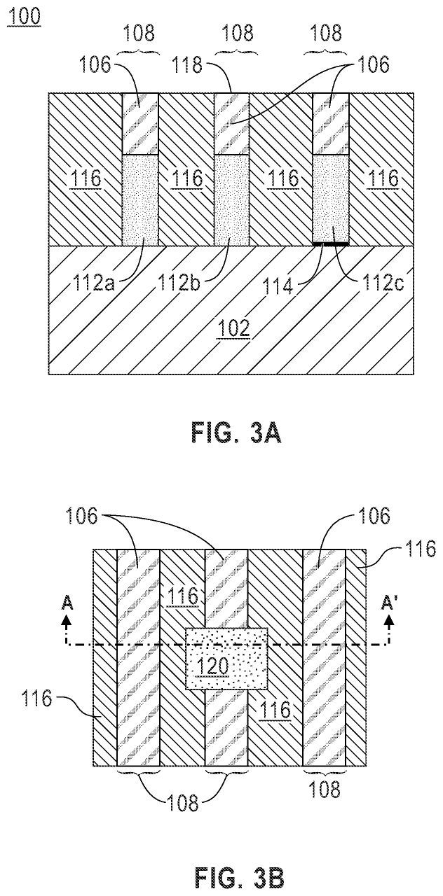

FIG. 3A and 3B are a schematic cross-sectional side view and a top view depicting the semiconductor structure 100 of FIG. 1 at a subsequent fabrication stage, in accordance with one embodiment of the present invention. FIG. 3A shows a scaffolding material 116 around the subtractive lines 108. As used in this application, around the subtractive lines 108 means that the scaffolding material 116 fills in the spaces 110 and contacts the subtractive lines 108 on all exposed sides. The scaffolding material 116 may then be planarized to reveal a top side 118 of the sacrificial hard mask 106.

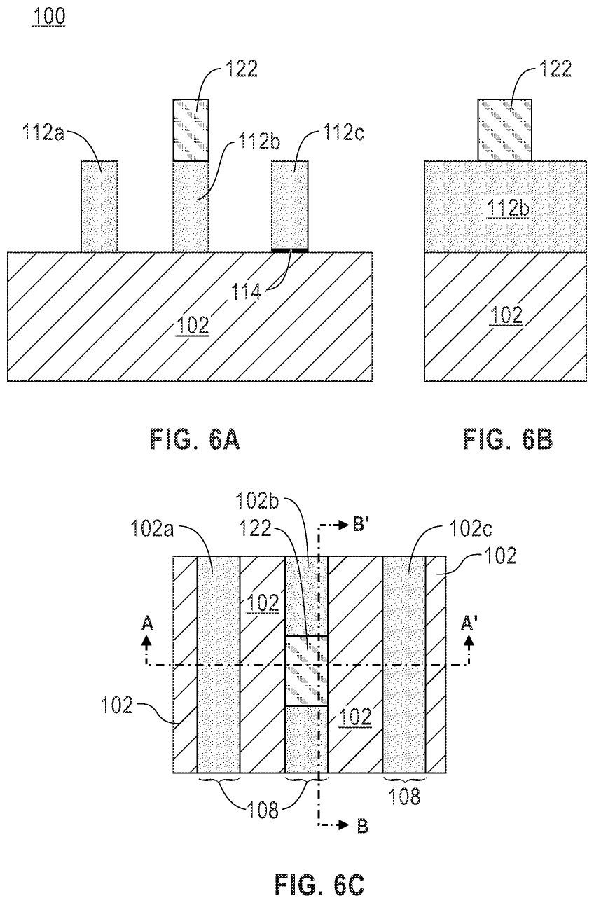

The scaffolding material 116 may include a spin-on-glass (SOG), or other dielectric materials that are etch selective to the substrate 102 and the bottom metal layer wires 112a, b, c during its removal step (FIG. 6). The top side 118 may be planarized (e.g., using chemical-mechanical planarization) so that the scaffolding material 116 and the sacrificial hard mask 106 are level with each other and flat. FIG. 3B shows an additional view illustrating that the sacrificial hard mask 106 is exposed even after the deposition of the scaffolding material 116.

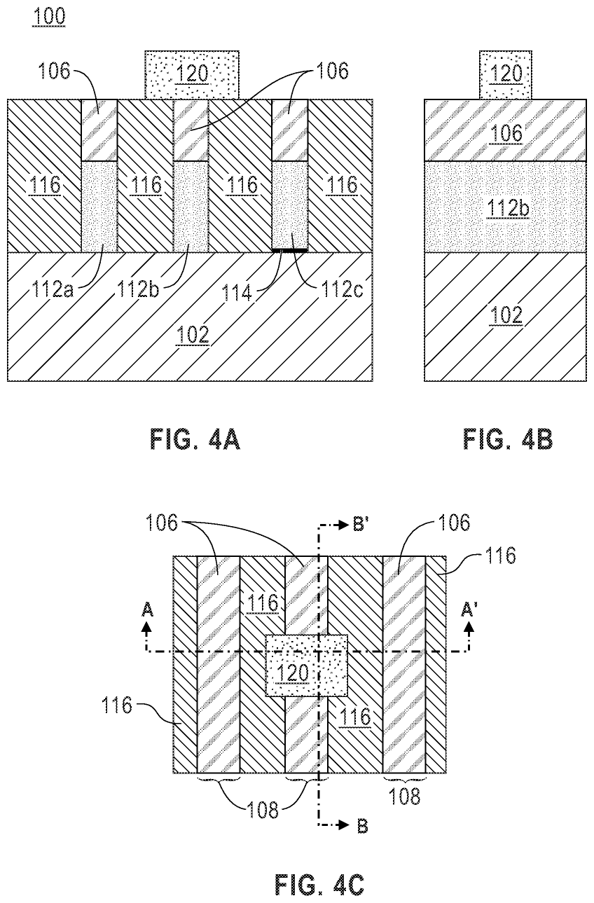

FIG. 4A, 4B, and 4C are schematic cross-sectional side views and a top view depicting the semiconductor structure 100 of FIG. 1 at a subsequent fabrication stage, in accordance with one embodiment of the present invention. FIG. 4A shows the formation of a via mask 120 over the sacrificial hard mask 106 and the scaffolding material 116. FIG. 4B is a cross-sectional view of the semiconductor structure 100 along line B-B′ in FIG. 4C, and also shows the via mask 120 with the sacrificial hard mask 106 underneath. The via mask 120 may be applied as a blanket layer and then subsequently patterned (e.g., lithographically) so that the illustrated via mask 120 remains.

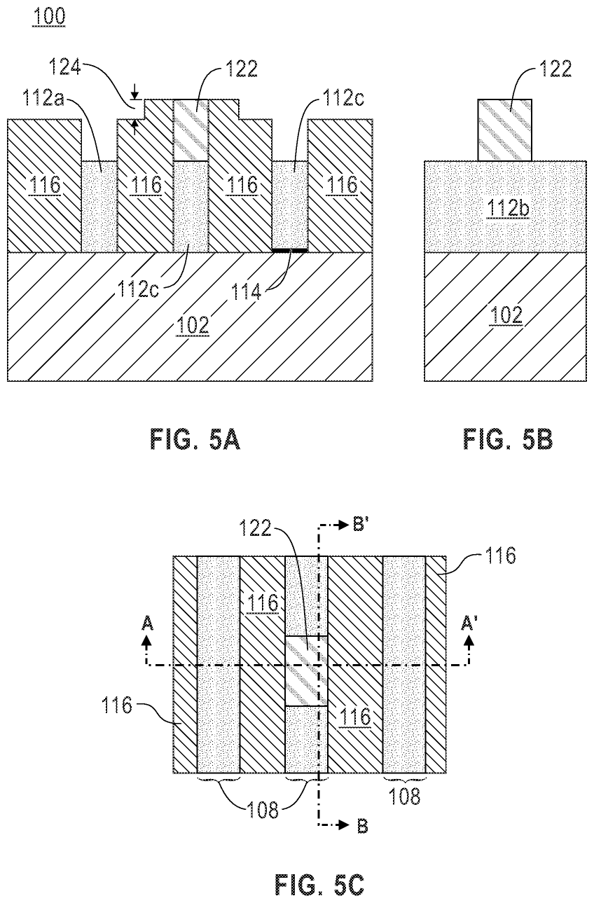

FIG. 5A, 5B, and 5C are schematic cross-sectional side views and a top view depicting the semiconductor structure 100 of FIG. 1 at a subsequent fabrication stage, in accordance with one embodiment of the present invention. FIG. 5A shows the step of etching the sacrificial hard mask 106 that is not covered by the via mask 120, to form a sacrificial via 122, and the subsequent removal of the via mask 120 from the semiconductor structure 100. The sacrificial hard mask 106 may be etched using directional etch processes such as, but not limited to, reactive ion etch (RIE). The sacrificial via 122 is protected during etching of the sacrificial hard mask 106 by the via mask 120. The directional etch process used on the sacrificial hard mask 106, in certain embodiments, may etch the scaffolding material 116 as well. FIG. 5A, for example, shows a gouging distance 124 that is the result of the directional etching of the scaffolding material 116 during the etching of the sacrificial hard mask 106. The directional etching, however, does not gouge or otherwise react with the bottom metal layer wires 112a, b, c. The via mask 120 is removed after the etching of the sacrificial hard mask 106. The via mask 120 is etch selectively removed so that the sacrificial via 122 and the bottom metal layer wires 112a, b, c are not affected.

FIG. 5B shows a cross-sectional side view of the semiconductor structure 100 at the angle indicated by line B-B′ in FIG. 5C. FIG. 5B shows the substrate 102, the second bottom metal layer wire 112b, and the sacrificial via 122. FIG. 5B also shows that a majority of the sacrificial hard mask 106 has been etched away above the second bottom metal layer wire 112b, without etching the second bottom metal layer wire 112b.

FIG. 6A, 6B, and 6C are schematic cross-sectional side views and a top view depicting the semiconductor structure 100 of FIG. 1 at a subsequent fabrication stage, in accordance with one embodiment of the present invention. FIG. 6A shows the scaffolding material 116 having been removed. The scaffolding material 116 is removed etch selectively without affecting the sacrificial via 122, the bottom metal layer wires 112a, b, c, or the substrate 102. FIG. 6B shows the same view of the semiconductor structure 100 as FIG. 5B since none of the scaffolding material 116 was visible along that cross-section. The sacrificial via 122 is unsupported, and protrudes at a uniform width above the second bottom metal layer wire 112b that was unaffected by the deposition or removal of the scaffolding material 116. FIG. 6C is a schematic top view that shows the substrate 102 revealed after the removal of the scaffolding material 116 from around the subtractive lines 108.

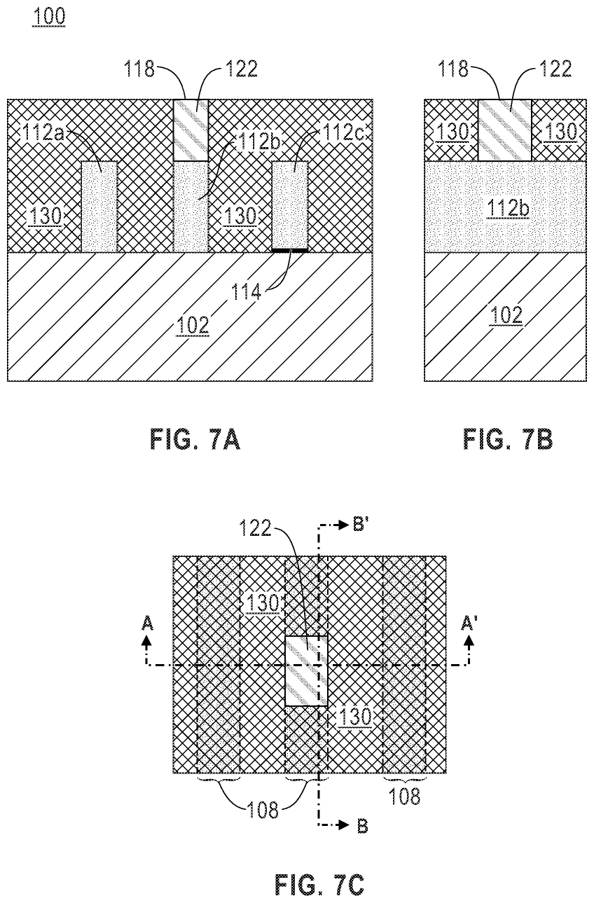

FIG. 7A, 7B, and 7C are schematic cross-sectional side views and a top view depicting the semiconductor structure 100 of FIG. 1 at a subsequent fabrication stage, in accordance with one embodiment of the present invention. FIG. 7A shows a low-κ layer 130 deposited around the subtractive lines 108 and the sacrificial via 122. Around the subtractive line 108 means that the low-κ layer 130 fills in between the subtractive lines 108 on all exposed sides. The low-κ layer 130 may then be planarized to reveal the top side 118 of the sacrificial via 122. In certain embodiments, the low-κ layer 130 is deposited around the subtractive lines 108 such that the top side 118 remains exposed without planarization. FIG. 7B adds a view showing that the sacrificial via 122 is surrounded on all lateral sides by the low-κ layer 130. FIG. 7C shows a schematic top view that shows that the only surfaces exposed are the low-κ layer 130 and the top side 118 of the sacrificial via 122.

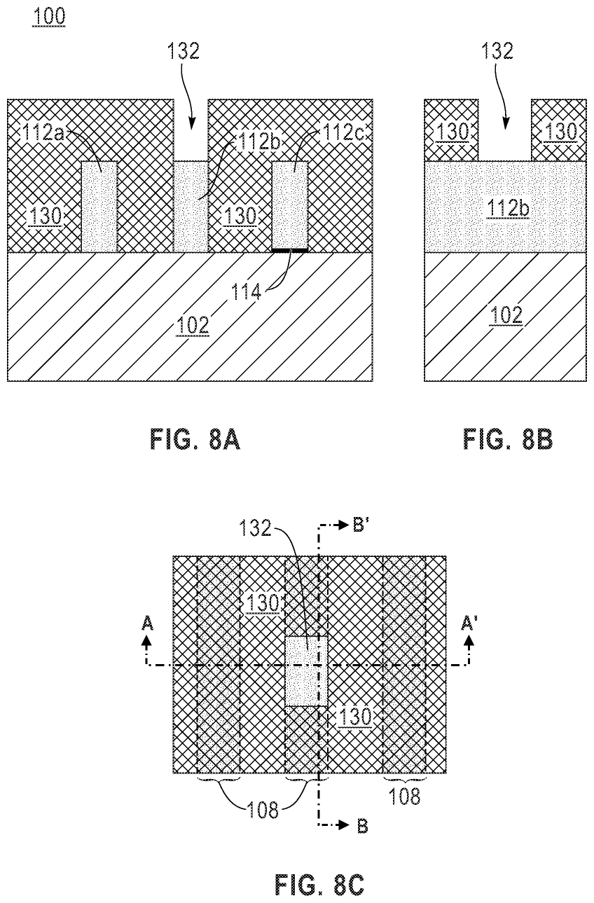

FIG. 8A, 8B, and 8C are schematic cross-sectional side views and a top view depicting the semiconductor structure 100 of FIG. 1 at a subsequent fabrication stage, in accordance with one embodiment of the present invention. FIGS. 8A, 8B, and 8C show the step of removing the sacrificial via 122 to form a via hole 132 within the low-κ layer 130. In the top view of FIG. 8C, the second bottom metal layer wire 112b is visible at the bottom of the via hole 132. The sacrificial via 122 is removed using a selective etch process which does not affect the low-κ layer 130 or the second bottom metal layer wire 112b.

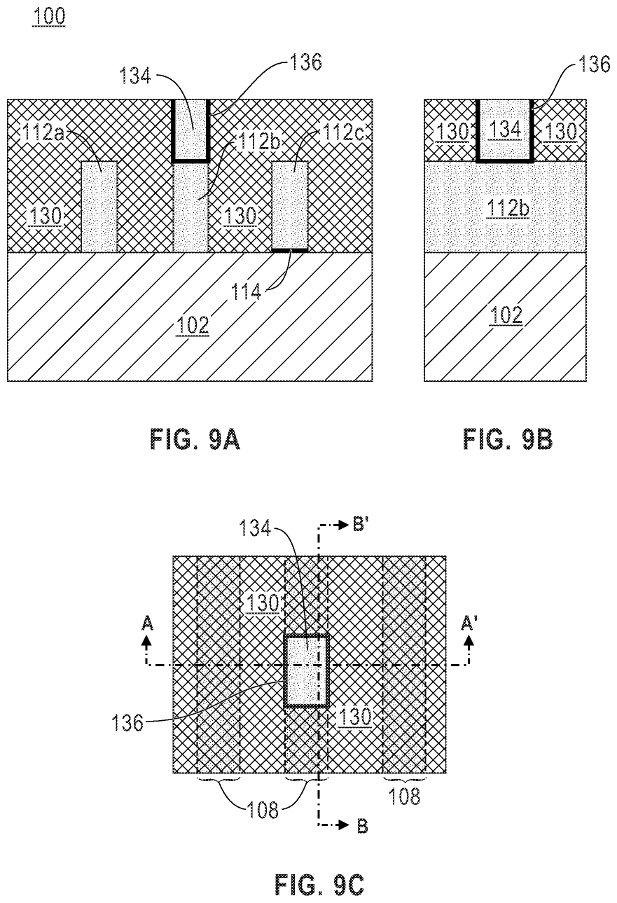

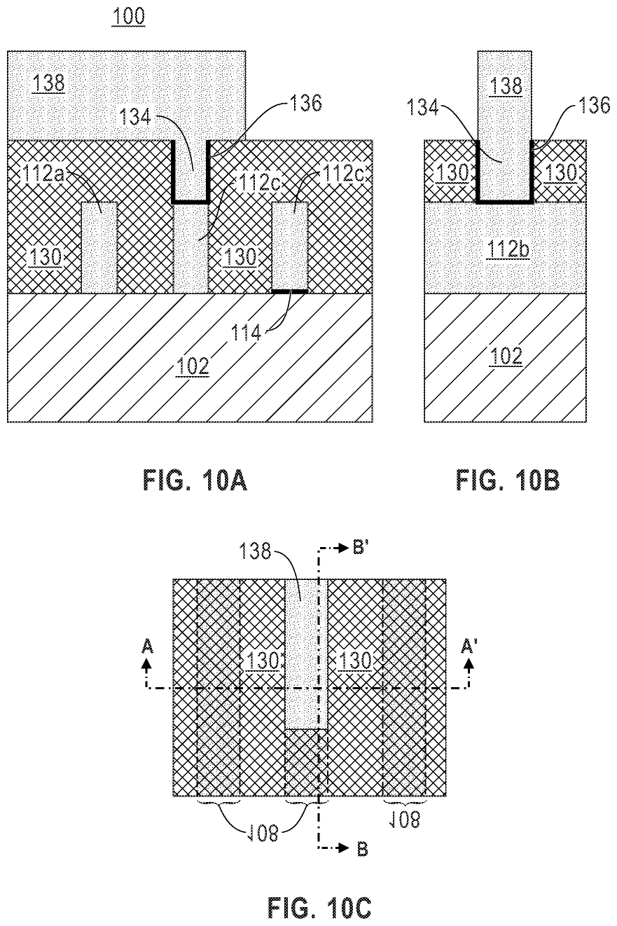

FIG. 9A, 9B, and 9C are schematic cross-sectional side views and a top view depicting the semiconductor structure 100 of FIG. 1 at a subsequent fabrication stage, in accordance with one embodiment of the present invention. FIGS. 9A, 9B, and 9C show the via hole 132 having been metallized to form a top via 134. The top via 134 includes a conductive material such as copper, tungsten, aluminum, cobalt, or other metals to electrically connect the bottom metal layer wires 112a, b, c to metal layers above the top via 134 and the low-κ layer 130 (e.g., top metal layer wire 136 illustrated in FIGS. 10A, 10B).

The top via 134 may include a via liner 136 that is deposited within the via hole 132 before forming the top via 134. The via liner 136 may include a material such as TaN or TiN to improve adhesion the top via 134 to the low-κ layer 130. The forming of the top via 134 may include metallizing the via hole 132 with a metal that is different from a metal of the bottom metal layer 104. Furthermore, forming the bottom metal layer 104 from one metal and forming the top via 134 from another metal is generally not possible when top via is formed by subtractive manner of tall metal line. The top via 134 may include a via width that is equal to the bottom metal layer wire 112b width. In the context of this application, having a width that is equal to another width means that the widths are substantially the same, on the scale of the specific fabricated component. In the specific instance of the top via 134 and the bottom metal layer wire 112b width, having an “equal” width means that any difference between the width of the top via 134 and the bottom metal layer wire 112b is approximately the thickness of the via liner 136, and not greater.

FIG. 10A, 10B are schematic cross-sectional side views and FIG. 10C is a schematic top view depicting the semiconductor structure 100 at a subsequent fabrication stage of the processing method, in accordance with one embodiment of the present invention. FIGS. 10A, 10B, and 10C show a top metal layer wire 138 electrically connected to the top via 134. The top metal layer wire 138 may be formed in a similar process to the bottom metal layer wires 112a, b, c, but typically runs perpendicular to the length of the bottom metal layer wires 112a, b, c. The top metal layer wire 138 may also be formed from a metal that is different from the top via 134. In certain embodiments, the semiconductor structure 100 may be formed with a top metal layer liner between the top via and the top metal layer wire 138.

The integrated circuit chips resulting from the processes described herein can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method of forming a semiconductor structure, comprising:
forming a subtractive line from a bottom metal layer and a sacrificial hard mask above the bottom metal layer;
depositing a scaffolding material around the subtractive line;
forming a via mask over a via portion of the sacrificial hard mask and the scaffolding material;
etching the sacrificial hard mask that is not covered by the via mask, to form a sacrificial via;
removing the via mask and the scaffolding material;
depositing a low-x layer around the subtractive line and the sacrificial via;
removing the sacrificial via to form a via hole within the low-x layer; and
forming a top via by metallizing the via hole.

2. The method of claim 1, further comprising planarizing the low-x layer.

3. The method of claim 1, further comprising forming a via liner within the via hole before forming the top via.

4. The method of claim 1, further comprising forming the bottom metal layer and the sacrificial hard mask on a substrate comprising transistor devices.

5. The method of claim 4, further comprising forming a substrate liner between the substrate and the bottom metal layer.

6. The method of claim 1, further comprising forming a top metal layer wire electrically connected to the top via.

7. The method of claim 1, wherein forming the top via comprises metallizing the via hole with a metal that is different from a metal of the bottom metal layer.

8. A semiconductor structure, comprising:
a bottom metal layer wire comprising a wire width;
a top via above the metal layer wire, wherein the top via comprises a via width that is equal to the wire width; and
a low-κ layer surrounding the metal layer wire and the top via.

9. The semiconductor structure of claim 8, wherein the bottom metal layer wire comprises a first material and the top via comprises a second material that is different from the first material.

10. The semiconductor structure of claim 8, wherein the top via comprises lateral sides that are perpendicular to a top surface of the low-K layer.

11. The semiconductor structure of claim 8, further comprising a via liner between the metal layer wire and the top via.

12. The semiconductor structure of claim 11, wherein the via liner comprises lateral sides between the top via and the low-κ layer.

13. The semiconductor structure of claim 8, wherein the metal layer wire comprises a selection from the group consisting of copper, aluminum, tungsten, cobalt, ruthenium, molybdenum, rhodium, and nibium.

14. The semiconductor structure of claim 8, further comprising a substrate below the metal layer wire, wherein the substrate comprises transistor devices.

15. A method, comprising:
forming a subtractive line comprising a bottom metal layer wire;
forming a sacrificial top via above the bottom metal layer wire;
depositing a low-κ layer around the bottom metal layer wire and the sacrificial top via;
removing the sacrificial top via to form a via hole within the low-κ layer; and
forming a top via by metallizing the via hole.

16. The method of claim 15, further comprising forming a via liner within the via hole before forming the top via.

17. The method of claim 15, wherein forming the bottom metal layer wire comprises depositing a bottom metal layer on a substrate comprising transistor devices.

18. The method of claim 17, further comprising forming a substrate liner between the substrate and the bottom metal layer.

19. The method of claim 15, further comprising forming a top metal layer electrically connected to the top via.

20. The method of claim 15, wherein forming the top via comprises metallizing the via hole with a metal that is different from a metal of the bottom metal layer wire.
